(19) United States
(12) Patent Application Publication
(10) Pub. No.: US 2026/0331412 A1
(43) Pub. Date: Oct. 22, 2026

(54) Ion Milling Device, Section Milling Processing Method, and Section Milling Holder

(71) Applicant: Hitachi High-Tech Corporation, Minato-ku, Tokyo (JP)

(72) Inventors: Naohiro FUJITA, Tokyo (JP); Hisayuki TAKASU, Tokyo (JP); Hitoshi KAMOSHIDA, Tokyo (JP); Atsushi KAMINO, Tokyo (JP)

(21) Appl. No.: 19/109,806

(22) PCT Filed: Sep. 8, 2022
(86) PCT No.: PCT/JP2022/033809

§ 371 Date: Mar. 7, 2025

(51) Int. Cl. H01J 37/09; H01J 37/08; H01J 37/20; H01J 37/305

(52) U.S. Cl. CPC H01J 37/09; H01J 37/20; H01J 37/3053; H01J 37/08; H01J 2237/024; H01J 2237/2007; H01J 2237/202

(57) ABSTRACT

An ion milling device includes a sample stage (2) on which a section milling holder configured to hold a sample (1) and a shielding plate (3) is mounted, an ion gun (4) configured to emit a non-focused ion beam toward the sample, and a shielding plate driving unit (8) configured to change adhesion between the sample and the shielding plate and a position of the shielding plate relative to the sample in an edge direction along a boundary between the sample and the shielding plate held by the section milling holder.

### TECHNICAL FIELD

The present invention relates to an ion milling device, a section milling processing method, and a section milling holder.

### BACKGROUND ART

An ion milling device can obtain a smooth processed surface by irradiating a surface or a section of a sample (for example, metal, semiconductor, glass, and ceramic) with a non-focused ion beam (Ar ions or the like) that is accelerated to several kV and knocking atoms off the sample surface without stress by a sputtering phenomenon. This is an excellent feature for performing smoothing processing for observing a surface or a section of a sample using an electron microscope represented by a scanning electron microscope (SEM) or a transmission electron microscope (TEM).

PTL 1 discloses a method for producing a section observation sample in which an upper portion of a workpiece is covered with a shielding plate, and a portion protruding from the shielding plate is irradiated with an ion beam to perform etching, thereby mirror-polishing the sample in a portion along an edge of the shielding plate. According to PTL 1, by irradiating the portion with the ion beam while moving the shielding plate by a reciprocating motion of a rod fixed to one side surface of the shielding plate, a depth of a recess occurred in the shielding plate caused by the ion beam irradiation during processing of one sample can be reduced, and the life of the shielding plate can be extended.

### CITATION LIST

### Patent Literature

PTL 1: JP2012-2740A

### SUMMARY OF INVENTION

### Technical Problem

In order to obtain a clean section by the section milling processing using an ion milling device, it is necessary to bring the shielding plate and the sample into close contact with each other so that ions do not enter between the shielding plate and the sample. In the disclosure of PTL 1, when the shielding plate is moved in a state where the shielding plate and the sample are in close contact with each other, a position of the sample interposed between the shielding plate and a sample stage may be displaced due to the action of friction between the shielding plate and the sample. Therefore, the ion beam irradiation is performed in a state where the adhesion between the shielding plate and the sample is reduced.

Since the technique disclosed in PTL 1 can reduce damage to the shielding plate due to the ion beam irradiation, it is considered that the technique is also effective in a case where section milling processing is performed for a long time, for example, when a section of a thick sample is exposed. However, performing the ion beam irradiation for a long time in a state where the adhesion between the shielding plate and the sample is reduced leads to a reduction in the accuracy of the section. In order to disperse damage to the shielding plate caused by the ion beam irradiation without reducing the accuracy of the section, it is necessary to perform control such that an appropriate degree of adhesion between the sample and the shielding plate is obtained when the sample is processed and when the shielding plate is moved.

### Solution to Problem

An ion milling device according to an aspect of an embodiment of the invention includes a sample stage on which a section milling holder configured to hold a sample and a shielding plate is mounted, an ion gun configured to emit a non-focused ion beam toward the sample, and a shielding plate driving unit configured to change adhesion between the sample and the shielding plate and a position of the shielding plate relative to the sample in an edge direction along a boundary between the sample and the shielding plate held by the section milling holder.

### Advantageous Effects of Invention

A processing range in the depth direction in section milling processing can be expanded. Other technical problems and novel features will become apparent from description of the present description and the accompanying drawings.

### BRIEF DESCRIPTION OF DRAWINGS

FIG. 1 is a diagram illustrating an overall o configuration of an ion milling device.

FIG. 2 is a view illustrating states of a shielding plate and a sample subjected to section milling processing.

FIG. 3A is a view illustrating adhesion between the sample and the shielding plate.

FIG. 3B is a view illustrating adhesion between the sample and the shielding plate.

FIG. 4A is a front view illustrating a section milling holder.

FIG. 4B is a side view illustrating the section milling holder.

FIG. 4C is a schematic view illustrating a movement operation of the shielding plate.

FIG. 5 is a schematic view illustrating a state in which the section milling holder is attached to a motor unit.

FIG. 6 is a flowchart illustrating section milling processing accompanying with a movement operation of the shielding plate.

### DESCRIPTION OF EMBODIMENTS

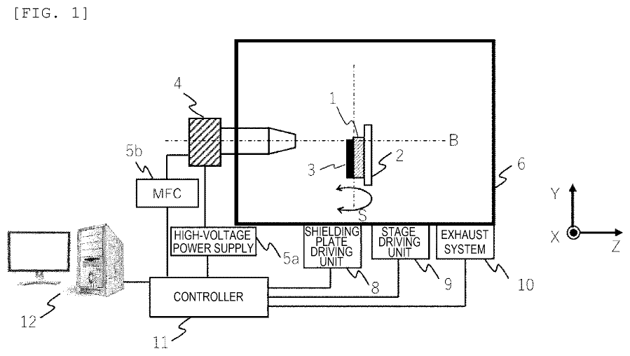

FIG. 1 is a diagram illustrating an overall configuration of an ion milling device. A sample 1 is placed on a sample stage 2, and the sample 1 is irradiated with an ion beam from an ion gun 4. The ion gun 4 employs a Penning method effective for downsizing a structure. In the ion gun of the Penning type, argon ions are generated by causing electrons generated by Penning discharge to collide with argon gas inside the ion gun, and the generated argon ions are accelerated and emitted as an ion beam. Therefore, a discharge voltage for generating Penning discharge and an acceleration voltage for accelerating argon ions are applied to the ion gun 4 from a high-voltage power supply 5a, and argon gas whose flow rate is controlled by a mass flow controller (MFC) 5b is supplied to the ion gun 4.

A shielding plate 3 for shielding the ion beam emitted from the ion gun 4 to the sample 1 is disposed on the sample 1, and a portion of the sample 1 exposed in a manner of protruding from an end surface of the shielding plate 3 is milled by the ion beam (section milling). The sample stage 2 is driven by a stage driving unit 9 in section milling processing. For example, the stage driving unit 9 causes the sample stage 2 to perform a swing operation about a swing axis S (Y direction) set to be orthogonal to an ion beam center B of the ion beam and a slide operation along an edge direction along a boundary between the sample 1 and the shielding plate 3 (in a direction (X direction) orthogonal to the ion beam center B and the swing axis S when the sample 1 faces the ion gun 4). A processed surface can be smoothed by the swing operation of swinging the sample 1 around the swing axis S in a predetermined angle range (swing angle). A processing width in the edge direction can be widened by the slide operation of moving the sample 1 back and forth in the edge direction around the ion beam center B. The ion milling processing is performed in a sample chamber 6 evacuated by an exhaust system 10. Further, the ion milling device according to the embodiment includes a shielding plate driving unit 8 that moves the shielding plate 3 in the edge direction relative to the sample 1. Although the shielding plate driving unit 8 and the stage driving unit 9 are illustrated outside the sample chamber 6 in FIG. 1, only the presence of the driving units is schematically illustrated, and arrangement positions of the driving units are not limited. In FIG. 1, the sample 1 is illustrated in a simplified manner that the sample 1 is placed on the sample stage 2, but as will be described later, the sample 1 and the shielding plate 3 are held by a section milling holder, and the section milling holder is mounted on the sample stage 2.

Control of the ion milling device is performed by a computer 12 and a controller 11, and the computer 12 and the controller 11 may be collectively referred to as a control unit. The computer 12 sets an ion milling condition set by a user in the controller 11, and the controller 11 controls each configuration (the ion gun 4, the sample stage 2, the shielding plate 3, the exhaust system 10, and the like) of the ion milling device based on a set control value.

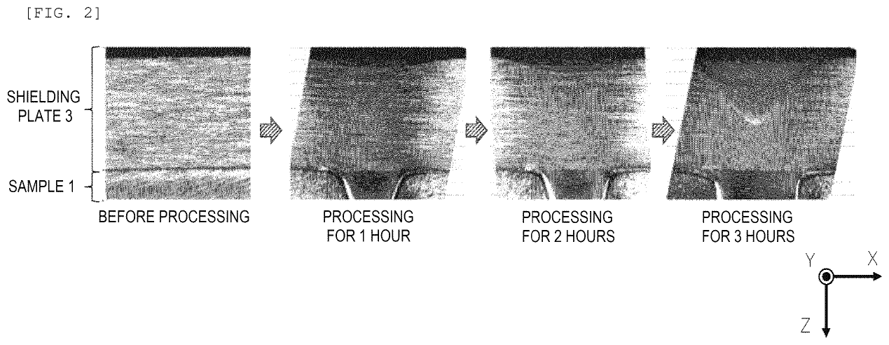

FIG. 2 is a view illustrating states of the shielding plate 3 and the sample 1 when the section milling processing is performed without moving the shielding plate 3. It can be seen that an upper end of the shielding plate 3 is also gradually milled as a processing time elapses. When the upper end of the shielding plate 3 is deeply cut by the ion beam, collision of ions with the sample 1 becomes non-uniform, and there is a concern that disturbance such as unevenness may occur on a section of the sample 1 subjected to the section milling processing. Therefore, the shielding plate driving unit 8 according to the embodiment moves the shielding plate 3 in the edge direction relative to the sample 1, thereby dispersing the influence of the ion beam emitted to the shielding plate 3 during the section milling processing in a wide range, and preventing a part of the shielding plate 3 from being deeply damaged and preventing the section of the sample 1 from being affected.

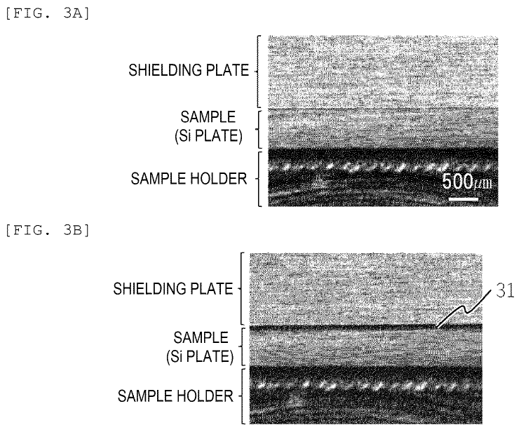

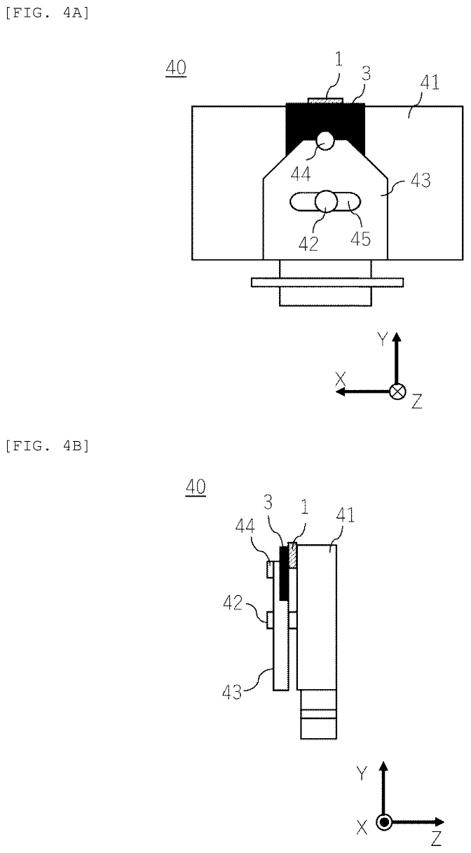

Here, it is desirable to strengthen adhesion between the sample 1 and the shielding plate 3 during the section milling processing. This is because ions may enter a gap between the sample 1 and the shielding plate 3 to cause disturbance in the section of the sample 1. On the other hand, when it is attempted to move the shielding plate 3 relative to the sample 1 in such a state of strong adhesion, the sample 1 may be displaced due to friction between the sample 1 and the shielding plate 3. FIGS. 3A and 3B are views illustrating adhesion between the sample 1 and the shielding plate 3. Here, the sample 1 is a Si plate. FIG. 3A shows a state in which the sample 1 is being processed, and the sample 1 and the shielding plate 3 are fixed without a gap. On the other hand, FIG. 3B shows a state in which the shielding plate 3 is moved in the edge direction, and a gap 31 occurs between the sample 1 and the shielding plate 3. Accordingly, it is possible to prevent a problem that the sample 1 moves on a sample holder due to movement of the shielding plate 3.

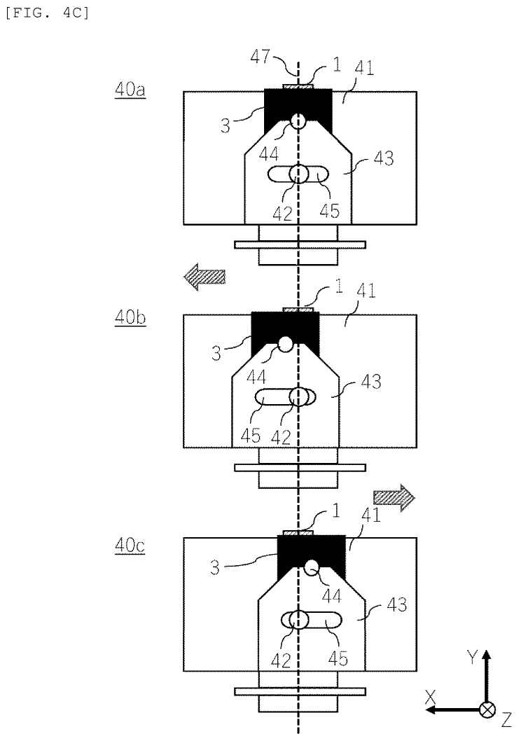

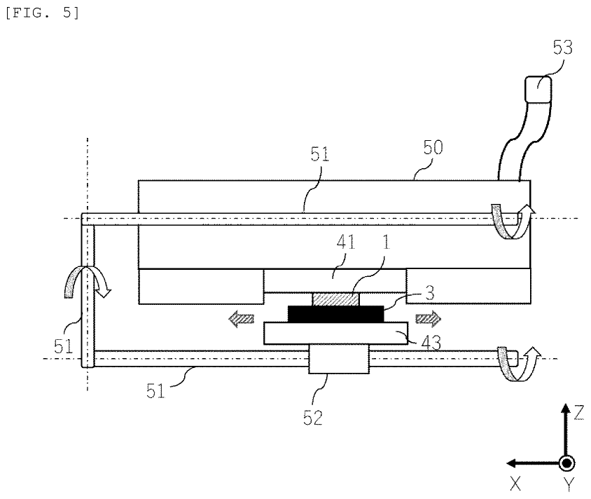

A structure of a section milling holder 40 for fixing the shielding plate 3 to the sample 1 will be described with reference to FIGS. 4A and 4B. FIG. 4A is a front view (as viewed from the ion gun 4), and FIG. 4B is a side view. The shielding plate 3 is fixed to a shielding plate holder 43 by a fixing screw 44. The shielding plate holder 43 is fixed to a sample holder 41 by a shielding plate fixing screw 42. The shielding plate holder 43 has a function of adjusting adhesion between the shielding plate 3 and the sample 1. By tightening the shielding plate fixing screw 42, adhesion can be enhanced, and by loosening the shielding plate fixing screw 42, adhesion can be weakened. A material of the shielding plate holder 43 is preferably a metal having a spring property, such as phosphor bronze. By tightening the shielding plate fixing screw 42, a force is applied in a Z direction, and high adhesion between the shielding plate 3 and the sample 1 is obtained.

The shielding plate fixing screw 42 is fixed to the sample holder 41 through a groove 45 of the shielding plate holder 43. The groove 45 has a length corresponding to a diameter of the shielding plate fixing screw 42 in a longitudinal direction (Y direction), and is formed elongated in a lateral direction (edge direction). Accordingly, the shielding plate 3 can be moved in an X direction relative to the sample 1 by changing a position of the shielding plate fixing screw 42 in a longitudinal direction (edge direction) of the groove 45.

FIG. 4C is a schematic view illustrating a movement operation of the shielding plate 3 on the section milling holder 40. On a section milling holder 40a, the shielding plate fixing screw 42 is positioned at the center of the groove 45 in the longitudinal direction, on a section milling holder 40b, the shielding plate fixing screw 42 is positioned on a right side of the center of the groove 45 in the longitudinal direction when viewed from the ion gun, and on a section milling holder 40c, the shielding plate fixing screw 42 is positioned on a left side of the center of the groove 45 in the longitudinal direction when viewed from the ion gun. In FIG. 4C, a center line 47 is illustrated in order to clearly show a relative positional relationship of the movement operation of the shielding plate 3. In this manner, by moving the shielding plate holder 43 to which the shielding plate 3 is fixed in the edge direction (left and right) relative to the sample holder 41, the shielding plate 3 can be moved in the edge direction (left and right) relative to the sample 1. When the shielding plate holder 43 is moved, the shielding plate fixing screw 42 needs to be loosened so that the sample 1 is not displaced.

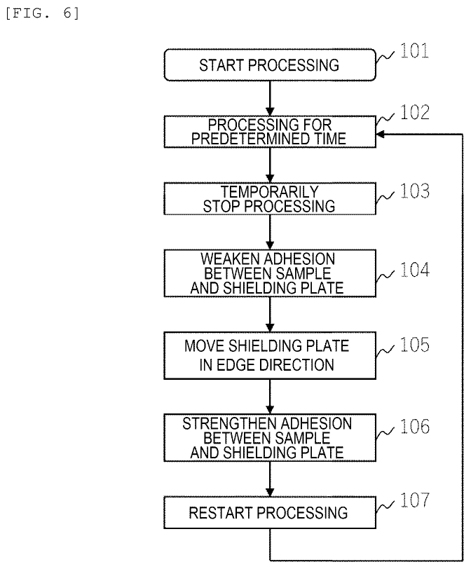

The shielding plate 3 is electrically controlled to perform a moving operation of the shielding plate 3 during the section milling processing. FIG. 5 is a schematic view (top view) illustrating a detailed configuration of the shielding plate driving unit 8 that moves the shielding plate 3. The shielding plate driving unit 8 includes a motor unit 50 attached to a back surface of the section milling holder 40, a rotation body 51 rotated by the motor unit 50, a shielding plate moving mechanism 52, and a power supply cable 53 that supplies power to the motor unit 50. The motor unit 50 rotates the rotation body 51 under the control of the controller 11. A rotation direction of the rotation body 51 can be switched between clockwise and counterclockwise. The shielding plate moving mechanism 52 uses rotation of the rotation body 51 as a driving source for rotating the shielding plate fixing screw 42 and as a driving source for moving a position of the shielding plate fixing screw 42 in the groove 45.

FIG. 6 is a flowchart illustrating the section milling processing accompanying with the movement operation of the shielding plate 3.
Step 101: A user places the sample 1 to be subjected to the section milling processing in the ion milling device, sets a processing condition for the sample 1 in the ion milling device from the computer 12, and then sends a processing start instruction.
Step 102: The control unit irradiates the sample 1 with the ion beam from the ion gun 4 for a predetermined time to perform processing (section milling processing) on the sample 1. The control unit also executes the swing operation and the slide operation according to the processing condition.
Step 103: The control unit temporarily stops the processing on the sample 1.
Step 104: The shielding plate driving unit 8 loosens the shielding plate fixing screw 42 of the section milling holder 40 to weaken the adhesion between the sample 1 and the shielding plate 3.
Step 105: In a state where the adhesion between the sample 1 and the shielding plate 3 is weakened, the shielding plate driving unit 8 moves the shielding plate 3 in the edge direction relative to the sample 1 by a certain amount.
Step 106: The shielding plate driving unit 8 tightens the shielding plate fixing screw 42 of the section milling holder 40 to strengthen the adhesion between the sample 1 and the shielding plate 3.
Step 107: The control unit resumes the processing and proceeds the processing to step 102.

The predetermined time for performing the processing in step 102 and the movement amount of the shielding plate 3 in step 105 may be dynamically adjusted according to the processing condition set in step 101.

The invention is not limited to the embodiments described above, and includes various modifications. For example, the embodiments described above have been described in detail to facilitate understanding of the invention, and the invention is not necessarily limited to those including all the configurations described. A part of a configuration of a certain embodiment can be replaced with a configuration of another embodiment, and a configuration of another embodiment can be added to a configuration of a certain embodiment. A part of a configuration of each embodiment may be added to, deleted from, or replaced with another configuration.

A part or all of the configurations, functions, processing units, processing methods, and the like described above may be implemented by hardware by, for example, designing with an integrated circuit. The above configurations, functions, or the like may be implemented by software by a processor interpreting and executing a program for implementing each function. Information such as a program, a table, and a file for implementing each function can be stored in a recording device such as a memory, a hard disk, and a solid state drive (SSD), or in a recording medium such as an IC card, a memory card, an optical recording medium, and a magnetic recording medium.

### REFERENCE SIGNS LIST

1: sample
2: sample stage
3: shielding plate
4: ion gun
5a: high-voltage power supply
5b: MFC
6: sample chamber
8: shielding plate driving unit
9: stage driving unit
10: exhaust system
11: controller
12: computer
31: gap
40: section milling holder
41: sample holder
42: shielding plate fixing screw
43: shielding plate holder
44: fixing screw
45: groove
47: center line
50: motor unit
51: rotation body
52: shielding plate moving mechanism
53: power supply cable

1. An ion milling device comprising:
a sample stage on which a section milling holder configured to hold a sample and a shielding plate is mounted;
an ion gun configured to emit a non-focused ion beam toward the sample; and
a shielding plate driving unit configured to change adhesion between the sample and the shielding plate and a position of the shielding plate relative to the sample in an edge direction along a boundary between the sample and the shielding plate held by the section milling holder.

2. The ion milling device according to claim 1, further comprising:
a control unit configured to control section milling processing on the sample, wherein
the control unit stops irradiation of the ion beam from the ion gun onto the sample, causes the shielding plate driving unit to move a position of the shielding plate relative to the sample in the edge direction by weakening the adhesion between the sample and the shielding plate, and restarts the irradiation of the ion beam from the ion gun onto the sample after strengthening the adhesion between the sample and the shielding plate.

3. The ion milling device according to claim 2, wherein
the control unit repeatedly performs the irradiation of the ion beam from the ion gun onto the sample for a predetermined time and the movement of the position of the shielding plate relative to the sample in the edge direction.

4. The ion milling device according to claim 1, further comprising:
a stage driving unit configured to cause the sample stage to perform a swing operation about a swing axis set to be orthogonal to an ion beam center of the ion beam and a slide operation of moving the sample in the edge direction.

5. The ion milling device according to claim 2, wherein
the section milling holder includes a shielding plate holder to which the shielding plate is fixed, a sample holder that sandwiches the sample together with the shielding plate, and a shielding plate fixing screw that fixes the shielding plate holder to the sample holder, and
the shielding plate fixing screw passes through a groove provided in the shielding plate holder and having a longitudinal direction in the edge direction, to fix the shielding plate holder to the sample holder.

6. The ion milling device according to claim 5, wherein
the shielding plate driving unit moves a position where the shielding plate fixing screw passes through the groove of the shielding plate holder.

7. The ion milling device according to claim 5, wherein
the shielding plate driving unit includes a motor unit, a rotation body rotated by the motor unit, and a shielding plate driving mechanism that rotates or moves the shielding plate fixing screw using rotation of the rotation body as a driving source.

8. The ion milling device according to claim 5, wherein
a material of the shielding plate holder is phosphor bronze.

9. A section milling processing method using an ion milling device,
the ion milling device including a sample stage on which a section milling holder configured to hold a sample and a shielding plate is mounted, an ion gun configured to emit a non-focused ion beam toward the sample, and a shielding plate driving unit configured to change adhesion between the sample and the shielding plate and a position of the shielding plate relative to the sample in an edge direction along a boundary between the sample and the shielding plate held by the section milling holder, the method comprising:
stopping irradiation of the ion beam onto the sample performed by the ion gun after a predetermined time;
moving, by the shielding plate driving unit, the position of the shielding plate relative to the sample in the edge direction by weakening the adhesion between the sample and the shielding plate, and strengthening the adhesion between the sample and the shielding plate again; and
restarting the irradiation of the ion beam onto the sample performed by the ion gun.

10. The section milling processing method according to claim 9, further comprising:
repeatedly performing the irradiation of the ion beam from the ion gun onto the sample for a predetermined time and the movement of the position of the shielding plate relative to the sample in the edge direction.

11. A section milling holder for holding a sample and a shielding plate for section milling processing performed by an ion milling device, the section milling holder comprising:
a shielding plate holder configured to allow the shielding plate to be fixed thereon;
a sample holder configured to sandwich the sample together with the shielding plate; and
a shielding plate fixing screw that fixes the shielding plate holder to the sample holder, wherein
the shielding plate fixing screw passes through a groove provided in the shielding plate holder and having a longitudinal direction in an edge direction along a boundary between the sample and the shielding plate, to fix the shielding plate holder to the sample holder.

12. The section milling holder according to claim 11, wherein a material of the shielding plate holder is phosphor bronze.
